(19) United States
(12) Patent Application Publication
(10) Pub. No.: US 2025/0160018 A1
(43) Pub. Date: May 15, 2025

(54) IMAGE SENSOR FOR AUTONOMOUS DRIVING AND ELECTRONIC APPARATUS INCLUDING THE SAME

(71) Applicant: SAMSUNG ELECTRONICS CO., LTD., Suwon-si (KR)

(72) Inventors: Younggeun ROH, Suwon-si (KR); Kyungbae Park, Suwon-si (KR); Sungyoung Yun, Suwon-si (KR); Younhee Lim, Suwon-si (KR); Hyochul Kim, Suwon-si (KR)

(21) Appl. No.: 18/917,389

(22) Filed: Oct. 16, 2024

(30) Foreign Application Priority Data
Nov. 14, 2023 (KR) 10-2023-0157692

(51) Int. Cl. H01L 27/146; G02B 5/20; H04N 25/13; H10K 39/32

(52) U.S. Cl. CPC H10F 39/8053; G02B 5/201; H04N 25/135; H10F 39/806; H10K 39/32

(57) ABSTRACT

An image sensor includes a sensor substrate including a plurality of photosensitive cells configured to sense light, a color filter layer on the sensor substrate, the color filter layer including a plurality of red color filters and a plurality of clear filters, the plurality of red color filters and the plurality of clear filters being alternately disposed, and a band stop filter facing the color filter layer and configured to have an absorption spectrum having an absorption peak wavelength of about 520 nanometers to about 620 nanometers.

### CROSS-REFERENCE TO RELATED APPLICATIONS

This application claims priority under 35 U.S.C. § 119 to Korean Patent Application No. 10-2023-0157692, filed on Nov. 14, 2023, in the Korean Intellectual Property Office, the disclosure of which is incorporated by reference herein in its entirety.

### BACKGROUND

### 1. Field

The present disclosure relates to image sensors, and more particularly, to an image sensor for autonomous driving and an electronic apparatus including the same.

### 2. Description of the Related Art

A related digital camera may produce color images by using a red/green/blue (RGB)-based image sensor. The RGB-based image sensor may sense (or detect) red light, green light, and/or blue light that may have passed through an RGB color filter and generate signals on respective red, green, and blue channels. The RGB-based image sensor may perform color imaging optimized for human vision. Alternatively, in an autonomous driving system such as, but not limited to, an advanced driving assistant system (ADAS), color information may be necessary for obtaining information around a vehicle. However, color information that may be needed for the autonomous driving system may not necessarily match human vision requirements. For example, an image sensor for an autonomous driving system may be designed to detect a minimum color spectrum that may be needed to determine a situation around a vehicle. Consequently, information throughput used by the autonomous driving system may be reduced.

### SUMMARY

One or more example embodiments of the present disclosure provide an image sensor for autonomous driving and an electronic apparatus including the image sensor.

According to an aspect of the present disclosure, an image sensor includes a sensor substrate including a plurality of photosensitive cells configured to sense light, a color filter layer on the sensor substrate, the color filter layer including a plurality of red color filters and a plurality of clear filters, the plurality of red color filters and the plurality of clear filters being alternately disposed, and a band stop filter facing the color filter layer and configured to have an absorption spectrum having an absorption peak wavelength of about 520 nanometers (nm) to about 620 nm.

In some embodiments, the band stop filter of the image sensor may directly contact upper surfaces of the plurality of red color filters.

In some embodiments, the band stop filter of the image sensor may include a plurality of first dielectric layers and at least one second dielectric layer. The at least one second dielectric layer may be disposed between two adjacent first dielectric layers of the plurality of first dielectric layers.

In some embodiments, the plurality of first dielectric layers may include a first dielectric material having a first refractive index, the at least one second dielectric layer may include a second dielectric material having a second refractive index, and the second refractive index may be different from the first refractive index.

In some embodiments, the first dielectric material of the plurality of first dielectric layers and the second dielectric material of the at least one second dielectric layer may each include at least one of TiO₂, SiO₂, SiN, Ta₂O₅, HfO₂, NbO₂, MgF₂, Si, Al₂O₃, or SiON.

In some embodiments, each layer of the plurality of first dielectric layers and the at least one second dielectric layer may have a thickness of about 10 nm to about 1000 nm.

In some embodiments, the band stop filter of the image sensor may include a first reflective layer, a second reflective layer facing the first reflective layer, and a dielectric layer between the first reflective layer and the second reflective layer.

In some embodiments, the first reflective layer and the second reflective layer may each include at least one reflective metal material from aluminum (Al), argentum (Ag), aurum (Au), tungsten (W), molybdenum (Mo), or nickel (Ni), and the first reflective layer and the second reflective layer may each have a thickness of about 0.5 nm to about 10 nm.

In some embodiments, the dielectric layer include at least one of TiO₂, SiO₂, SiN, Ta₂O₅, HfO₂, NbO₂, MgF₂, Si, Al₂O₃, or SiON.

In some embodiments, the first reflective layer and the second reflective layer may form a resonator, and a distance between the first reflective layer and the second reflective layer and a refractive index of the dielectric layer may be selected such that a resonant wavelength of the resonator matches the absorption peak wavelength of the band stop filter.

In some embodiments, the band stop filter of the image sensor may be spaced apart from the color filter layer and at least partially covering a region of the color filter layer.

In some embodiments, the band stop filter of the image sensor may include a plurality of first dielectric layers and a plurality of second dielectric layers that are alternately disposed. The plurality of first dielectric layers may include a first dielectric material having a first refractive index. The plurality of second dielectric layers may include a second dielectric material having a second refractive index. The second refractive index may be different from the first refractive index.

In some embodiments, the first dielectric material of the plurality of first dielectric layers and the second dielectric material of the plurality of second dielectric layers may each include at least one of TiO₂, SiO₂, SiN, Ta₂O₅, HfO₂, NbO₂, MgF₂, Si, Al₂O₃, or SiON.

In some embodiments, a difference between the first refractive index of the plurality of first dielectric layers and the second refractive index of the plurality of second dielectric layers may be less than or equal to 1. A full width at half maximum (FWHM) of the absorption spectrum of the band stop filter may be less than or equal to 100 nm.

According to an aspect of the present disclosure, an image sensor includes a red pixel including a first electrode, a second electrode, and a first active layer between the first electrode and the second electrode, and a clear pixel including a third electrode, a fourth electrode, and a second active layer between the third electrode and the fourth electrode. The first active layer includes a p-type organic semiconductor material configured to selectively absorb red light, and an n-type organic semiconductor material configured to receive electrons from the p-type organic semiconductor material that is excited by the absorbed red light. The first electrode and the second electrode form a resonator having a resonant wavelength of about 610 nm to about 630 nm.

In some embodiments, the first active layer may include a bulk heterojunction structure in which the p-type organic semiconductor material and the n-type organic semiconductor material are co-deposited in one layer.

In some embodiments, the first active layer may include a p-type organic semiconductor layer adjacent to the first electrode and an n-type organic semiconductor layer adjacent to the second electrode. The p-type organic semiconductor layer may include the p-type organic semiconductor material configured to selectively absorb red light. The n-type organic semiconductor layer may include the n-type organic semiconductor material configured to receive electrons from the p-type organic semiconductor material excited by the absorbed red light.

In some embodiments, the second active layer may include a first p-type organic semiconductor material configured to absorb red light, a second p-type organic semiconductor material configured to absorb green light, a third p-type organic semiconductor material configured to absorb blue light, and the n-type organic semiconductor material configured to receive electrons from excited p-type organic semiconductor material.

In some embodiments, the image sensor may further include a band stop filter facing the second electrode of the red pixel and configured to have an absorption spectrum with an absorption peak wavelength of about 520 nm to about 620 nm.

According to an aspect of the present disclosure, an electronic apparatus includes a lens assembly configured to form an optical image of a subject, an image sensor configured to convert the optical image formed by the lens assembly into an electrical signal, and a processor configured to process a signal generated by the image sensor. The image sensor includes a sensor substrate including a plurality of photosensitive cells configured to sense light, a color filter layer on the sensor substrate, the color filter layer including a plurality of red color filters and a plurality of clear filters, the plurality of red color filters and the plurality of clear filters being alternately disposed, and a band stop filter facing the color filter layer and configured to have an absorption spectrum having an absorption peak wavelength of about 520 nm to about 620 nm.

Additional aspects may be set forth in part in the description which follows and, in part, may be apparent from the description, and/or may be learned by practice of the presented embodiments.

### BRIEF DESCRIPTION OF THE DRAWINGS

The above and other aspects, features, and advantages of certain embodiments of the present disclosure may be more apparent from the following description taken in conjunction with the accompanying drawings, in which:

FIG. 1 is a schematic block diagram of an image sensor, according to an embodiment;

FIGS. 2A and 2B are diagrams showing examples of various pixel arrangements in a pixel array of an image sensor, according to embodiments;

FIGS. 3A and 3B are cross-sectional views schematically showing a structure of a pixel array in an image sensor, according to embodiments;

FIGS. 4 and 5 are cross-sectional views showing examples of various bandwidth pass filters, according to embodiments;

FIG. 6 is a graph showing an example transmission spectrum obtained through a combination of a band stop filter and a red color filter compared with a transmission spectrum of a red color filter, according to an embodiment;

FIG. 7 is a cross-sectional view schematically showing a structure of a pixel array in an image sensor, according to an embodiment;

FIG. 8 is a graph showing an example transmission spectrum obtained through a combination of a band stop filter and a red color filter shown in FIG. 7 compared with a transmission spectrum of a red color filter, according to an embodiment;

FIG. 9 is a cross-sectional view schematically showing a structure of a pixel array in an image sensor, according to an embodiment;

FIG. 10 is a cross-sectional view schematically showing a structure of a pixel array in an image sensor, according to an embodiment;

FIGS. 11A to 11Q are diagrams showing examples of chemical formulas of various p-type organic semiconductor materials that selectively absorb red light, according to embodiments;

FIG. 12 is a chemical formula showing an example of an n-type organic semiconductor material, according to an embodiment;

FIG. 13 is a diagram showing an example of an absorption peak wavelength of p-type organic semiconductor materials shown in FIGS. 11A to 11Q, according to embodiments;

FIG. 14 is a diagram showing an example of an absorption spectrum of a red pixel in the pixel array of FIG. 9, according to an embodiment;

FIG. 15 is a cross-sectional view schematically showing a structure of a pixel array in an image sensor, according to an embodiment;

FIG. 16 is a block diagram of an electronic device including an image sensor, according to an embodiment;

FIG. 17 is a block diagram of a camera module in FIG. 16, according to an embodiment;

FIG. 18 is a block diagram of an electronic apparatus including a multi-camera module, according to an embodiment; and

FIG. 19 is a detailed block diagram of a multi-camera module in the electronic device of FIG. 18, according to an embodiment.

### DETAILED DESCRIPTION

Reference is made to embodiments, examples of which are illustrated in the accompanying drawings, wherein like reference numerals refer to like elements throughout. In this regard, the present embodiments may have different forms and should not be construed as being limited to the descriptions set forth herein. Accordingly, the embodiments are merely described below, by referring to the figures, to explain aspects. As used herein, the term “and/or” includes any and all combinations of one or more of the associated listed items. Expressions such as “at least one of,” when preceding a list of elements, modify the entire list of elements and do not modify the individual elements of the list. That is, as used herein, each of such phrases as “A or B,” “at least one of A and B,” “at least one of A or B,” “A, B, or C,” “at least one of A, B, and C,” and “at least one of A, B, or C,” may include any one of, or all possible combinations of the items enumerated together in a corresponding one of the phrases.

Hereinafter, an image sensor for autonomous driving and an electronic apparatus including the image sensor is described with reference to accompanying drawings. The embodiments of the disclosure are capable of various modifications and may be embodied in many different forms. In the drawings, sizes of components in the drawings may be exaggerated for convenience of explanation.

When a layer, a film, a region, or a panel is referred to as being “on” another element, it may be directly on/under/at left/right sides of the other layer or substrate, or intervening layers may also be present. In addition, when an element or layer is referred to as “covering” another element or layer, the element or layer may cover at least a portion of the other element or layer, where the portion may include a fraction of the other element or may include an entirety of the other element. Similarly, when an element or layer is referred to as “penetrating” another element or layer, the element or layer may penetrate at least a portion of the other element or layer, where the portion may include a fraction of the other element or may include an entire dimension (e.g., length, width, depth) of the other element.

It is to be understood that although the terms “first,” “second,” and the like may be used to describe various components, these components should not be limited by these terms. These terms are only used to distinguish one component from another. These terms do not limit that materials or structures of components may be different from one another.

An expression used in the singular encompasses the expression of the plural, unless it has a clearly different meaning in the context. It is to be further understood that when a portion is referred to as “comprising” another component, the portion may not exclude another component but may further comprise another component unless the context states otherwise.

In addition, the terms such as “ . . . unit”, “module”, and the like provided herein may indicate a unit performing a function or operation, and may be realized by hardware, software, or a combination of hardware and software.

The use of the terms of “the above-described” and similar indicative terms may correspond to both the singular forms and the plural forms.

Also, the steps of all methods described herein may be performed in any suitable order unless otherwise indicated herein or otherwise clearly contradicted by context. Also, the use of all exemplary terms (for example, etc., and the like) is only to describe a technical spirit in detail, and the scope of rights is not limited by these terms unless the context is limited by the claims.

Reference throughout the present disclosure to “one embodiment,” “an embodiment,” “an example embodiment,” or similar language may indicate that a particular feature, structure, or characteristic described in connection with the indicated embodiment is included in at least one embodiment of the present solution. Thus, the phrases “in one embodiment”, “in an embodiment,” “in an example embodiment,” and similar language throughout this disclosure may, but do not necessarily, all refer to the same embodiment. The embodiments described herein are example embodiments, and thus, the disclosure is not limited thereto and may be realized in various other forms.

The embodiments herein may be described and illustrated in terms of blocks, as shown in the drawings, which carry out a described function or functions. These blocks, which may be referred to herein as units or modules or the like, or by names such as device, logic, circuit, controller, counter, comparator, generator, converter, or the like, may be physically implemented by analog and/or digital circuits including one or more of a logic gate, an integrated circuit, a microprocessor, a microcontroller, a memory circuit, a passive electronic component, an active electronic component, an optical component, and the like.

In the present disclosure, the articles “a” and “an” are intended to include one or more items, and may be used interchangeably with “one or more.” Where only one item is intended, the term “one” or similar language is used. For example, the term “a processor” may refer to either a single processor or multiple processors. When a processor is described as carrying out an operation and the processor is referred to perform an additional operation, the multiple operations may be executed by either a single processor or any one or a combination of multiple processors.

As used herein, each of the terms “Al₂O₃”, “HfO₂”, “MgF₂”, “NbO₂”, “SiN”, “SiO₂”, “SiON”, “Ta₂O₅”, “TiO₂”, and the like may refer to a material made of elements included in each of the terms and is not a chemical formula representing a stoichiometric relationship.

Hereinafter, various embodiments of the present disclosure are described with reference to the accompanying drawings.

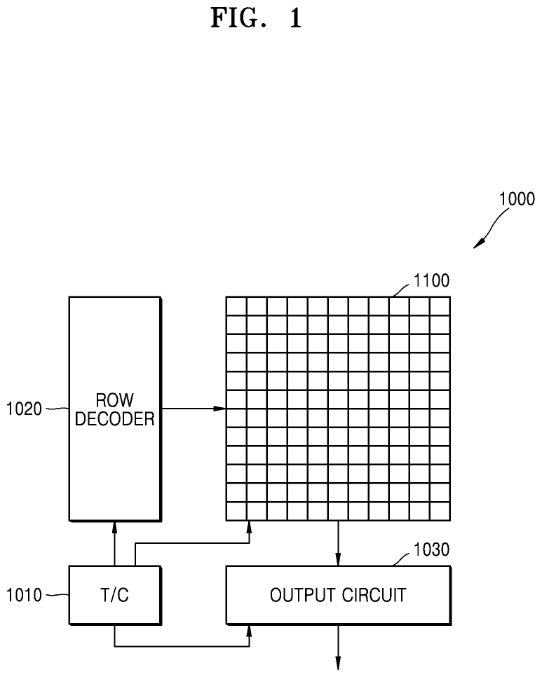

FIG. 1 is a schematic block diagram of an image sensor 1000, according to an embodiment. Referring to FIG. 1, the image sensor 1000 may include a pixel array 1100, a timing controller (T/C) 1010, a row decoder 1020, and an output circuit 1030. The image sensor 1000 may be and/or may include a charge-coupled device (CCD) image sensor, a complementary metal oxide semiconductor (CMOS) image sensor, or the like.

The pixel array 1100 may include pixels that may be two-dimensionally (2D) disposed in a plurality of rows and columns. The row decoder 1020 may select one of the rows in the pixel array 1100 in response to a row address signal output from the timing controller 1010. The output circuit 1030 may output a photosensitive signal, in a line unit, from a plurality of pixels disposed in the selected row. To this end, the output circuit 1030 may include a column decoder and an analog-to-digital converter (ADC). For example, the output circuit 1030 may include a plurality of ADCs that may be disposed respectively in columns between the column decoder and the pixel array 1100 or one ADC disposed at an input end or an output end of the column decoder. The timing controller 1010, the row decoder 1020, and the output circuit 1030 may be implemented in one chip or in separate chips. At least one processor for processing an image signal output from the output circuit 1030 may be implemented in one chip together with the timing controller 1010, the row decoder 1020, and the output circuit 1030.

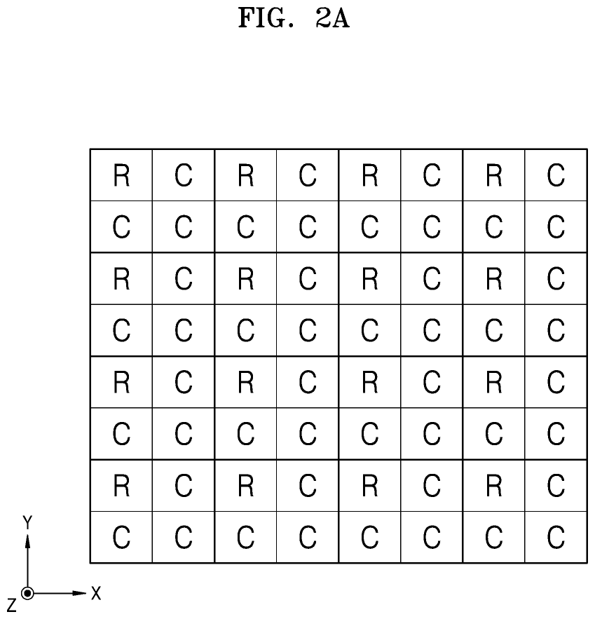

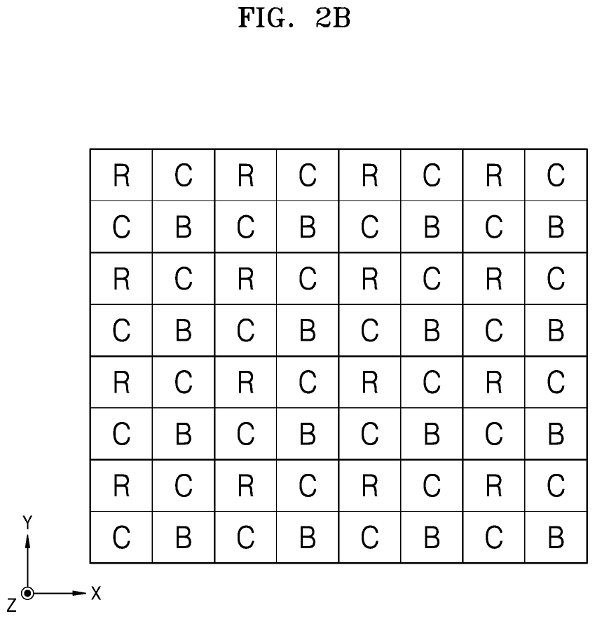

The pixel array 1100 may include a plurality of pixels that sense light of different wavelengths. The pixel arrangement may be implemented in various ways. For example, FIGS. 2A and 2B show examples of various pixel arrangements in the pixel array 1100 of the image sensor 1000.

Referring to FIG. 2A, one unit pattern of the pixel array 1100 may include four quadrant regions, and a red pixel R may be arranged in one of the quadrant regions and clear pixels C may be arranged in the remaining three regions. The unit patterns may be repeatedly two-dimensionally (2D) disposed in a first direction (an X direction) and a second direction (a Y direction). The red pixel R may include a red color filter for sensing red light, and the clear pixel C may not include a color filter and may sense light of all wavelengths. For example, a substantially similar and/or the same arrangement may be obtained by replacing the green and blue pixels, except for the red pixel, in a Bayer pattern of a color image sensor with the clear pixels C. Such a pixel arrangement may be referred to as a red, clear, clear, clear (RCCC) arrangement.

However, the present disclosure is not limited in this regard. That is, the pixel array 1100 may be disposed in various arrangement patterns, other than the above-described pattern. For example, referring to FIG. 2B, a red, clear, clear, blue (RCCB)-arrangement in which clear pixels C are used instead of green pixels in the Bayer pattern may be used in the pixel array 1100. That is, in four quadrant regions of one unit pattern, one red pixel R and one blue pixel B may be arranged in a diagonal direction, and two clear pixels C may be arranged in another diagonal direction. Such a pixel arrangement may be referred to as an RCCB arrangement.

The image sensor 1000 having the pixel array 1100 shown in FIG. 2A or FIG. 2B may improve identification with respect to a certain color (e.g., red color) while increasing sensitivity in a low-illuminance environment. In addition, because the number of color channels is reduced, the image processing may be simplified. For example, the image sensor 1000 may be mounted in an autonomous driving system for a vehicle and may be used to sense front traffic signals.

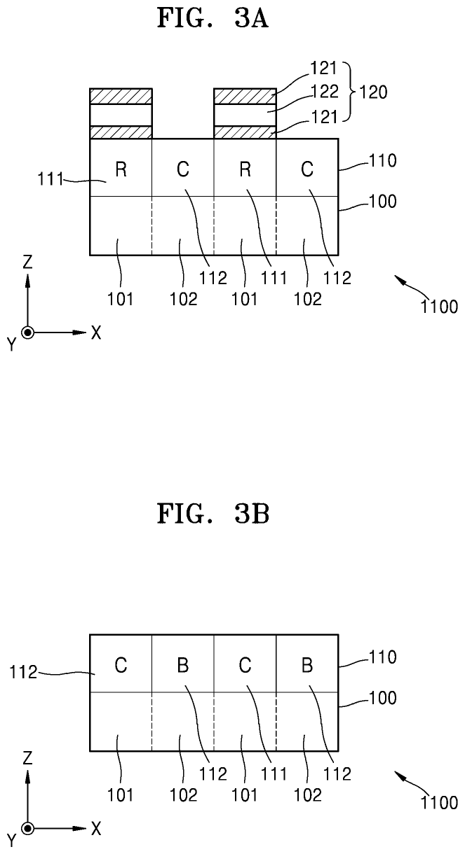

FIGS. 3A and 3B are cross-sectional views schematically showing a structure of the pixel array 1100 in the image sensor 1000 according to an embodiment. FIG. 3A schematically shows a cross-section of the pixel array 1100 taken along the first direction (X-direction), and FIG. 3B schematically shows a cross-section of the pixel array 1100, taken along the first direction (X-direction) at a location different from that of FIG. 3A in the second direction (Y-direction).

Referring to FIGS. 3A and 3B, the pixel array 1100 may include a sensor substrate 100, a color filter layer 110 arranged on the sensor substrate 100, and a plurality of band stop filters 120 arranged to face the color filter layer 110.

The sensor substrate 100 may include a plurality of photosensitive cells (e.g., first photosensitive cell 101, second photosensitive cell 102, and third photosensitive cell 103) sensing incident light. For example, the sensor substrate 100 may include a plurality of first photosensitive cells 101, a plurality of second photosensitive cells 102, and a plurality of third photosensitive cells 103 that may convert incident light into electrical signals to generate image signals. The plurality of first photosensitive cells 101, the plurality of second photosensitive cells 102, and the plurality of third photosensitive cells 103 may be two-dimensionally (2D) arranged in the first direction and the second direction on the sensor substrate 100. For example, in the cross-section shown in FIG. 3A, the plurality of first photosensitive cells 101 and the plurality of second photosensitive cells 102 may be alternately arranged in the first direction, and in a cross-section at a different location in the second direction that is perpendicular to the first direction, as shown in FIG. 3B, the plurality of second photosensitive cells 102 and the plurality of third photosensitive cells 103 may be alternately arranged in the first direction.

The color filter layer 110 may include a plurality of color filters that may be arranged on a light-receiving surface of the sensor substrate 100 to transmit light of a certain wavelength band and absorb light of another wavelength band. For example, the color filter layer 110 may include a plurality of red color filters 111 transmitting red light and absorbing light of different wavelength bands, a plurality of clear filters 112 transmitting light of all wavelength bands, and a plurality of blue color filters 113 transmitting blue light and absorbing light of different wavelength bands. In the color filter layer 110, the plurality of red color filters 111, the plurality of clear filters 112, and the plurality of blue color filters 113 may be two-dimensionally (2D) arranged in the first direction and the second direction. For example, in the cross-section shown in FIG. 3A, the plurality of red color filters 111 and the plurality of clear filters 112 may be alternately arranged in the first direction, and in a cross-section at a different location in the second direction as shown in FIG. 3B, the plurality of clear filters 112 and the plurality of blue color filters 113 may be alternately arranged in the first direction.

In an example, the clear filter 112 may include a dielectric material having a wide transmission band with respect to the entire range of a visible ray. Alternatively or additionally, the clear filter 112 may include air. That is, the clear filter 112 may denote an empty space.

Each of the plurality of red color filters 111 may be arranged to face a corresponding first photosensitive cell, from among the plurality of first photosensitive cells 101, in one-to-one correspondence in the third direction (e.g., Z-direction). Each of the plurality of clear filters 112 may be arranged to face a corresponding second photosensitive cell, from among the plurality of second photosensitive cells 102, in the third direction. In addition, each of the plurality of blue color filters 113 may be arranged to face a corresponding third photosensitive cell, from among the plurality of third photosensitive cells 103, in the third direction. Accordingly, each of the plurality of first photosensitive cells 101 may sense the red light that has passed through the red color filter 111 corresponding thereto. Each of the plurality of second photosensitive cells 102 may sense the visible light of all wavelengths. Each of the plurality of third photosensitive cells 103 may sense the blue light that has passed through the blue color filter 113 corresponding thereto.

FIGS. 3A and 3B show an example in which the pixel array 1100 has the RCCB arrangement of FIG. 2B, however, the present disclosure is not limited in this regard. For example, the pixel array 1100 may have the RCCC arrangement shown in FIG. 2A. In such an example, the blue color filter 113 of the color filter layer 110 may be replaced with the clear filter 112. In the cross-section of the sensor substrate 100 shown in FIG. 3B, the plurality of second photosensitive cells 102 may be only arranged, and in the cross-section of the color filter layer 110 shown in FIG. 3B, the plurality of clear filters 112 may be only arranged.

Each of the plurality of band stop filters 120 may be arranged in direct contact with the upper surface of the plurality of red color filters 111 of the color filter layer 110. That is, each of the plurality of band stop filters 120 may be arranged to face a corresponding red color filter, from among the plurality of red color filters 111, in one-to-one correspondence in the third direction. The band stop filter may not be arranged on the upper surfaces of the clear filter 112 and the blue color filter 113.

The plurality of band stop filters 120 may be configured to block the light of yellow (Y) wavelength band that may be adjacent to the red wavelength band. For example, the plurality of band stop filters 120 may be configured to at least partially block (e.g., absorb or reflect) the light within the wavelength band range from about 520 nanometers (nm) to about 620 nm, in the incident light. By arranging the band stop filter 120 on the red color filter 111, in the transmission spectrum of the red color filter 111, a portion overlapping the yellow wavelength band may be removed. As another example, the light of the yellow wavelength band is rarely incident on the first photosensitive cells 101, and the red light may be only incident on the first photosensitive cells 101. When the image sensor 1000 is used, for example, a red signal and a yellow signal in a traffic light may be distinguished from each other. That is, an error of misrecognizing the yellow signal as the red signal may be potentially prevented and/or reduced.

Referring to FIG. 3A, each band stop filter 120 may include two first dielectric layers 121 and a second dielectric layer 122 disposed between the two first dielectric layers 121. That is, each band stop filter 120 may include the first dielectric layer 121 arranged on the red color filter 111, the second dielectric layer 122 arranged on the first dielectric layer 121, and the first dielectric layer 121 arranged on the second dielectric layer 122. The first dielectric layer 121 may include a first dielectric material having a first refractive index, and the second dielectric layer 122 may include a second dielectric material having a second refractive index that is different from the first refractive index. For example, the first dielectric material of the first dielectric layer 121 and the second dielectric material of the second dielectric layer 122 may each include at least one dielectric material such as, but not limited to, TiO₂, SiO₂, SiN, Ta₂O₅, HfO₂, NbO₂, MgF₂, Si, Al₂O₃, and SiON.

An absorption spectrum of the band stop filter 120 may be determined by the thickness and refractive index of the first dielectric layer 121 and the thickness and refractive index of the second dielectric layer 122. For example, the thickness and refractive index of the first dielectric layer 121 and the thickness and refractive index of the second dielectric layer 122 may be selected such that the peak wavelength of the absorption spectrum (e.g., absorption peak wavelength) may be within a wavelength range of about 520 nm to about 620 nm. For example, a reference thickness and reference refractive index of each of the first and second dielectric layers 121 and 122 may be selected such that an optical thickness (e.g., the product of physical thickness and refractive index) of each of the first and second dielectric layers 121 and 122 is about a fourth (e.g., ¼) of the absorption peak wavelength. As a result, the thickness and refractive index of the first or second dielectric layer may be increased and/or reduced based on the reference thickness and the reference refractive index in order to finely adjust the bandwidth and the absorption peak wavelength of the absorption spectrum. Thus, the actual thickness and actual refractive index of each of the first and second dielectric layers 121 and 122 may be selected in such a manner. The thicknesses of the two first dielectric layers 121 may be substantially similar and/or equal to each other. However, the present disclosure is not limited in this regard. That is, the thicknesses of the two first dielectric layers 121 may be different. For example, one first dielectric layer 121 and one second dielectric layer 122 may each have a thickness of about 10 nm to about 1000 nm.

For example, when the first dielectric layer 121 includes TiO₂ and the second dielectric layer 122 includes SiO₂, the thickness of the first dielectric layer 121 in the lower portion coming into contact with the color filter layer 110 may be about 79 nm, the thickness of the second dielectric layer 122 is about 101 nm, and the thickness of the first dielectric layer 121 in the upper portion is about 61 nm. Consequently, the absorption peak wavelength of the absorption spectrum of the band stop filter 120 may be about 585 nm. However, the present disclosure is not limited in this regard, and the thicknesses and/or materials of the first dielectric layer and the second dielectric may have other values and/or materials without departing from the scope of the present disclosure.

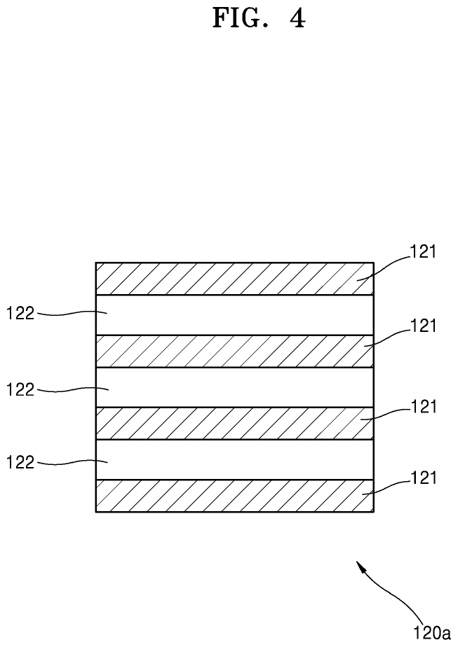

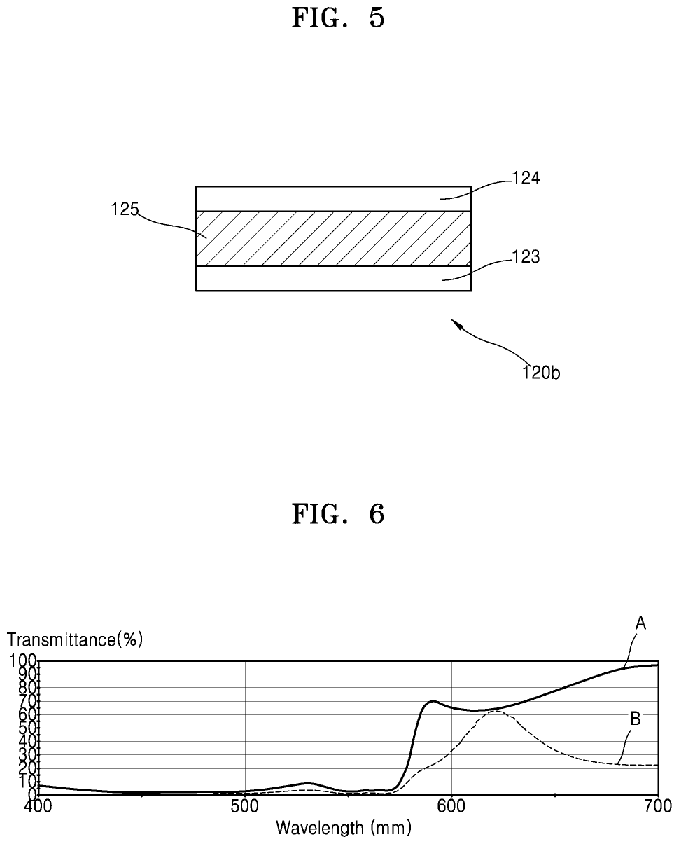

FIG. 3A shows that the band stop filter 120 may include two first dielectric layers 121 and one second dielectric layer 122. However, the present disclosure is not limited in this regard. For example, the band stop filter 120 may have other various configurations. FIGS. 4 and 5 are cross-sectional views showing examples of various bandwidth pass filters, according to an embodiment.

Referring to FIG. 4, a band stop filter 120a may include a plurality of first dielectric layers 121 and a plurality of second dielectric layers 122, which may be alternately arranged. For example, in FIG. 4, the band stop filter 120a may include four (4) first dielectric layers 121 and three (3) second dielectric layers 122. However, the present disclosure is not limited thereto. That is, the band stop filter 120a may include other numbers of first dielectric layers 121 and/or second dielectric layers 122. In addition, the number of first dielectric layers 121 may be greater than the number of second dielectric layers 122. However, the present disclosure is not limited thereto. That is, the number of first dielectric layers 121 may be equal to that of the second dielectric layers 122. Referring to FIGS. 3A and 4, the band stop filter 120 may include at least two first dielectric layers 121 and at least one second dielectric layer 122, and the second dielectric layer 122 may be disposed between two adjacent first dielectric layers 121. The first dielectric layers 121 may have a different reflective index from that of the second dielectric layers 122, resulting in a configuration where dielectric layers with two different reflective indices are alternately stacked.

Referring to FIG. 5, a band stop filter 120b may include a first reflective layer 123 and a second reflective layer 124 facing each other, and a dielectric layer 125 disposed between the first reflective layer 123 and the second reflective layer 124. The first reflective layer 123 and the second reflective layer 124 may include, for example, at least one reflective metal material from aluminum (Al), argentum (Ag), aurum (Au), tungsten (W), molybdenum (Mo), and nickel (Ni). The dielectric layer 125 may include, for example, at least one dielectric material such as, but not limited to, TiO₂, SiO₂, SiN, Ta₂O₅, HfO₂, NbO₂, MgF₂, Si, Al₂O₃, and SiON. The thickness of each of the first reflective layer 123 and the second reflective layer 124 may be about 0.5 nm to about 10 nm. The first reflective layer 123 and the second reflective layer 124 may form a resonator. A distance between the first reflective layer 123 and the second reflective layer 124 and the refractive index of the dielectric layer 125 may be selected such that a resonant wavelength of the resonator matches the absorption peak wavelength of the absorption spectrum of the band stop filter 120b. In such a configuration, in the incident light incident on the band stop filter 120b, the light having a wavelength corresponding to the resonant wavelength may be absorbed by the dielectric layer 125 while resonating in the resonator.

FIG. 6 is a graph showing an example transmission spectrum obtained through a combination of the band stop filter 120 and the red color filter 111 compared with a transmission spectrum of the red color filter 111. In FIG. 6, the graph indicated by “A” shows a spectrum distribution of light that has only passed through the red color filter 111, and the graph indicated by “B” shows a spectrum distribution of light that has passed through the band stop filter 120 and the red color filter 111. Referring to FIG. 6, when only the red color filter 111 is used (e.g., graph “A”), the light incident on the first photosensitive cell 101 after passing through the red color filter 111 may include yellow light of a wavelength band of about 570 nm to about 600 nm, as well as the red light. In an embodiment, the absorption peak wavelength of the absorption spectrum of the band stop filter 120 may be about 585 nm. In such an embodiment, a relatively large amount of the light having the wavelength band of about 520 nm to about 620 nm may be absorbed by the band stop filter 120. Consequently, when the band stop filter 120 is used with the red color filter 111 (e.g., graph “B”), the yellow light may be mostly blocked by the band stop filter 120, and the light incident on the first photosensitive cell 101 may have a spectrum distribution having a peak wavelength of about 620 nm, and the light having a wavelength band of about 570 nm to about 600 nm may be reduced by about 60%, when compared to graph “A”. As a result, most of the light incident on the first photosensitive cell 101 may be red light.

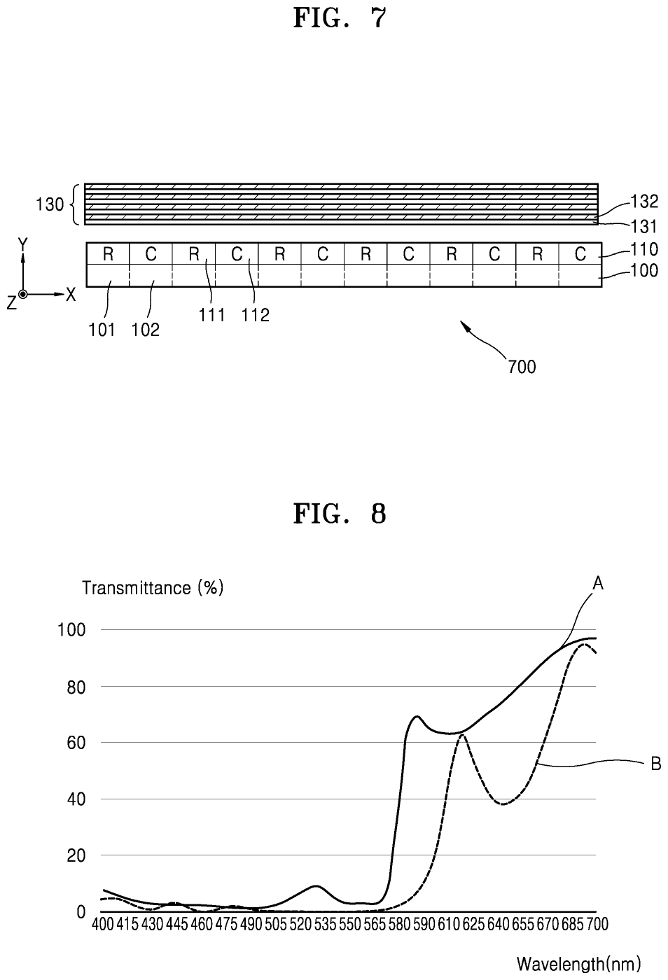

FIG. 7 is a cross-sectional view schematically showing a structure of a pixel array in an image sensor, according to an embodiment. In the pixel array 1100 described with reference to FIGS. 3A and 3B, the band stop filter 120 may be provided to correspond to the red color filter 111 and/or the first photosensitive cell 101. However, a band stop filter may be provided to cover all photosensitive cells and color filters. Referring to FIG. 7, a pixel array 700 may include a band stop filter 130 provided to cover the entire area of the color filter layer 110. For example, an area of the band stop filter 130 may be greater than that of the sensor substrate 100 and/or that of the color filter layer 110. The band stop filter 130 may be arranged to be spaced apart from the color filter layer 110. For example, on an optical path between an objective lens and the image sensor 1000 in a camera module, the band stop filter 130 that is greater than the diameter of an optical beam may be arranged.

The band stop filter 130 may include a plurality of first dielectric layers 131 and a plurality of second dielectric layers 132 that may be alternately arranged. The first dielectric layer 131 may include a first dielectric material having a first refractive index, and the second dielectric layer 132 may include a second dielectric material having a second refractive index that is different from the first refractive index. For example, the first dielectric material of the first dielectric layer 131 and the second dielectric material of the second dielectric layer 132 may each include at least one dielectric material such as, but not limited to, TiO₂, SiO₂, SiN, Ta₂O₅, HfO₂, NbO₂, MgF₂, Si, Al₂O₃, and SiON.

The thickness and refractive index of the first dielectric layer 131 and the thickness and refractive index of the second dielectric layer 132 may be selected such that the peak wavelength of the absorption spectrum (e.g., absorption peak wavelength) of the band stop filter 130 may be within a wavelength range of about 520 nm to about 620 nm. For example, a reference thickness and a reference refractive index of each of the first and second dielectric layers 131 and 132 may be selected such that the optical thickness of each of the first and second dielectric layers 131 and 132 is about a fourth (e.g., ¼) of the absorption peak wavelength. As a result, the thickness and refractive index of each of the first and second dielectric layers may be increased and/or reduced based on the reference thickness and reference refractive index in order to finely adjust the bandwidth and the absorption peak wavelength of the absorption spectrum. Accordingly, the actual thickness and actual refractive index of each of the first and second dielectric layers 131 and 132 may be selected in such a manner. In the band stop filter 130, the thicknesses of the plurality of first dielectric layers 131 may be equal and/or different, and the thicknesses of the plurality of second dielectric layers 132 may be equal and/or different. For example, each of the plurality of first dielectric layers 131 and the plurality of second dielectric layers 132 may have a thickness of about 10 nm to about 1000 nm.

In an embodiment, the light that has passed through the band stop filter 130 may be incident on the clear filter 112 and the blue color filter 113, as well as, the red color filter 111. As such, the intensity of light incident on the second photosensitive cell 102 and the third photosensitive cell 103 respectively corresponding to the clear filter 112 and the blue color filter 113 may be reduced. In order to reduce the decrease in the intensity of light incident on the second photosensitive cell 102 and the third photosensitive cell 103, the band stop filter 130 may be designed to have a narrow bandwidth. For example, a full width at half maximum (FWHM) of the absorption spectrum of the band stop filter 130 may be less than or equal to about 100 nm. To this end, the band stop filter 130 may include two or more first dielectric layers 131 and two or more second dielectric layers 132. Alternatively or additionally, the difference between the first refractive index of the first dielectric layer 131 and the second refractive index of the second dielectric layer 132 may be relatively small. For example, the difference between the first refractive index of the first dielectric layer 131 and the second refractive index of the second dielectric layer 132 may be less than or equal to about 1. However, the present disclosure is not limited in this regard. For example, in some embodiments, the difference between the first and second refractive indexes may be less than or equal to about 0.8, or less than or equal to about 0.6.

FIG. 8 is a graph showing an example transmission spectrum obtained through a combination of the band stop filter 130 and the red color filter 111 shown in FIG. 7 compared with a transmission spectrum of the red color filter 111. In FIG. 8, the band stop filter 130 including four (4) first dielectric layers 131 formed of SiN and four (4) second dielectric layers 132 formed of SiO₂ may be used. The absorption peak wavelength of the absorption spectrum of the band stop filter 130 may be about 540 nm. In FIG. 8, the graph indicated by “A” shows a spectrum distribution of light that has passed only through the red color filter 111, and the graph indicated by “B” shows a spectrum distribution of light that has passed through the band stop filter 130 and the red color filter 111. Referring to FIG. 8, the light having a wavelength band of about 570 nm to about 600 nm may be reduced by about 88% due to the band stop filter 130.

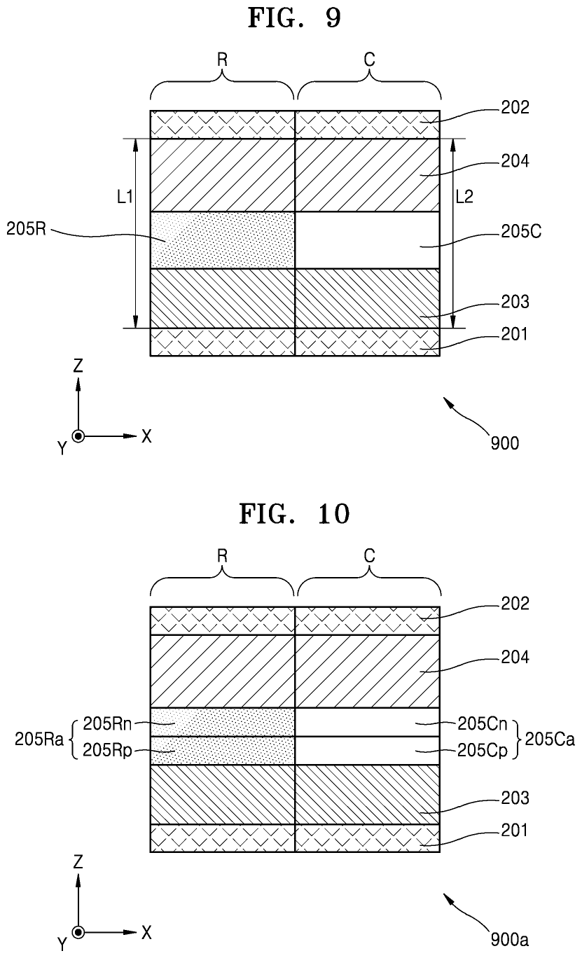

FIG. 9 is a cross-sectional view schematically showing a structure of a pixel array in an image sensor, according to an embodiment. Referring to FIG. 9, the pixel array 900 may include a red pixel R and a clear pixel C. Although FIG. 9 only shows one red pixel R and one clear pixel C, it is to be understood that the pixel array 900 may include a plurality of red pixels R and a plurality of clear pixels C that may be alternately arranged. Alternatively or additionally, the red pixels R and the clear pixels C in the pixel array 900 may be and/or may include organic photodetectors (OPDs), for example.

Each of the red pixels R may include a first electrode 201, a second electrode 202, and a first active layer 205R disposed between the first electrode 201 and the second electrode 202. In addition, each red pixel R may further include a hole transport layer (HTL) 203 disposed between the first electrode 201 and the first active layer 205R, and an electron transport layer (ETL) 204 disposed between the second electrode 202 and the first active layer 205R.

The first electrode 201 and the second electrode 202 of the red pixel R may form a resonator having a resonant wavelength within a red wavelength band. For example, an optical distance L1 between the first electrode 201 and the second electrode 202 may be selected such that a resonator having the resonant wavelength within a wavelength range of about 610 nm to about 630 nm may be formed.

Each clear pixel C may include the first electrode 201, the second electrode 202, and a second active layer 205C disposed between the first electrode 201 and the second electrode 202. In addition, each clear pixel C may further include the HTL 203 disposed between the first electrode and the second active layer 205C, and the ETL 204 disposed between the second electrode 202 and the second active layer 205C.

The first electrode 201 and the second electrode 202 of the clear pixel C may form a multi-mode resonator in which red light, green light, and blue light may all resonate. For example, an optical distance L2 between the first electrode 201 and the second electrode 202 in the clear pixel C may be selected such that a resonator having the resonant wavelength at the peak wavelength of the red wavelength band, the peak wavelength of the green wavelength band, and the peak wavelength of the blue wavelength band may be formed. Although, for convenience of description, FIG. 9 shows that the red pixel R and the clear pixel C have the same height, the present disclosure is not limited in this regard. That is, the red pixel R and the clear pixel C may have different heights. Therefore, the optical distance L1 between the first electrode 201 and the second electrode 202 in the red pixel R may be different from the optical distance L2 between the first electrode 201 and the second electrode 202 in the clear pixel C.

The first active layer 205R of the red pixel R may include an organic material absorbing red light. The first active layer 205R of the red pixel R may include, for example, a p-type organic semiconductor material selectively absorbing red light and an n-type organic semiconductor material receiving electrons from the p-type organic semiconductor material excited by the absorbed red light.

The second active layer 205C of the clear pixel C may include a panchromatic organic material. For example, the clear pixel C may include a p-type organic semiconductor material absorbing red light, a p-type organic semiconductor material absorbing green light, a p-type organic semiconductor material absorbing blue light, and an n-type organic semiconductor material receiving electrons from excited p-type organic semiconductor material.

FIG. 10 is a cross-sectional view schematically showing a structure of a pixel array in an image sensor, according to an embodiment. Each of the first active layer 205R and the second active layer 205C shown in FIG. 9 may have a bulk heterojunction structure in which a p-type organic semiconductor material and an n-type organic semiconductor material are co-deposited in one layer. However, the present disclosure is not limited thereto, and the p-type organic semiconductor material and the n-type organic semiconductor material may be individually deposited in separate layers, as shown in FIG. 10. That is, the red pixel R of a pixel array 900a may include a first active layer 205Ra having a dual-layered structure, and the clear pixel C may include a second active layer 205Ca having a dual-layered structure.

For example, the first active layer 205Ra of the red pixel R may include a p-type organic semiconductor layer 205Rp provided on the HTL 203, and an n-type organic semiconductor layer 205Rn disposed between the p-type organic semiconductor layer 205Rp and the ETL 204. That is, the p-type organic semiconductor layer 205Rp may be adjacent to the first electrode 201 and the n-type organic semiconductor layer 205Rn may be adjacent to the second electrode 202. The p-type organic semiconductor layer 205Rp may include a p-type organic semiconductor material selectively absorbing red light. The n-type organic semiconductor layer 205Rn may include an n-type organic semiconductor material receiving electrons from the p-type organic semiconductor material excited by the absorbed red light.

In an embodiment, a second active layer 205Ca of the clear pixel C may include the p-type organic semiconductor layer 205Cp arranged on the HTL 203 in the clear pixel C and the n-type organic semiconductor layer 205Cn disposed between the p-type organic semiconductor layer 205Cp and the ETL 204. That is, the p-type organic semiconductor layer 205Cp may be adjacent to the first electrode 201 and the n-type organic semiconductor layer 205Cn may be adjacent to the second electrode 202. The p-type organic semiconductor layer 205Cp may include a p-type organic semiconductor material absorbing red light, a p-type organic semiconductor material absorbing green light, and a p-type organic semiconductor material absorbing blue light.

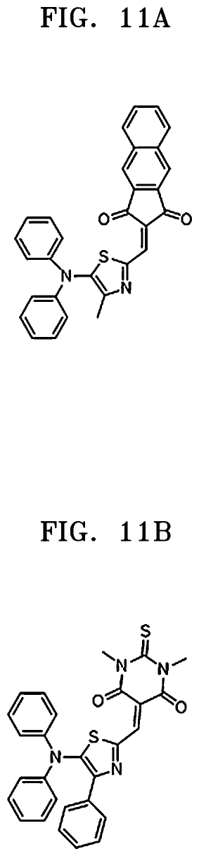

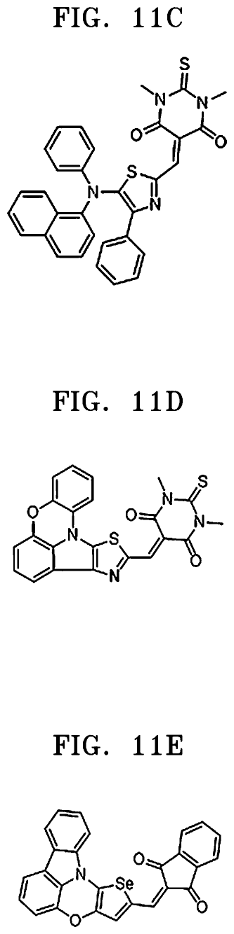

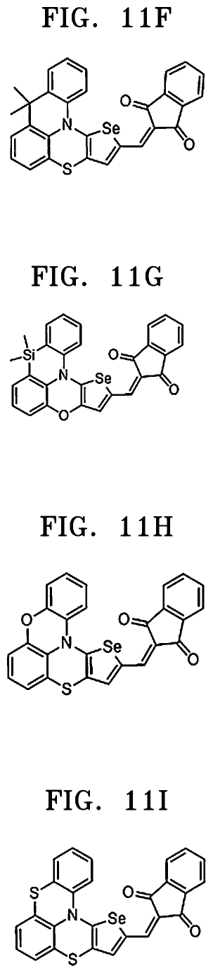

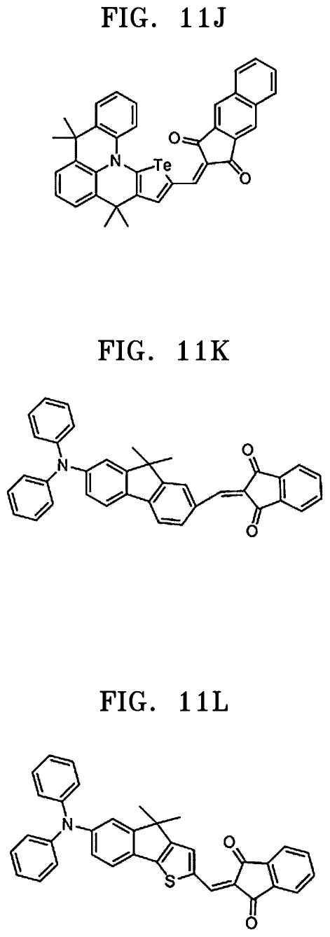

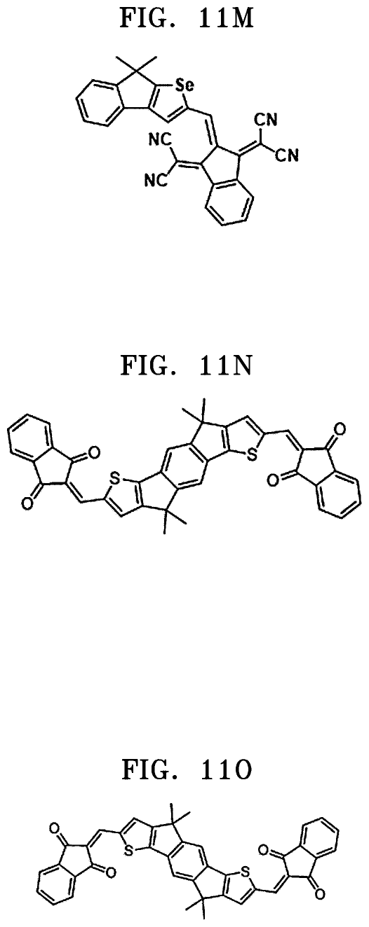

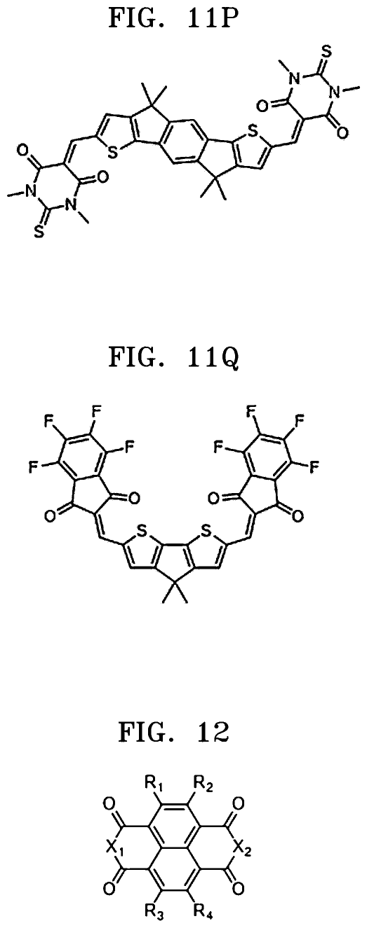

FIGS. 11A to 11Q are diagrams showing examples of chemical formulas of various p-type organic semiconductor materials that selectively absorb red light. The p-type organic semiconductor material selectively absorbing the red light as shown in FIGS. 11A to 11Q may include donor-TT-acceptor (D-TT-A)-based materials and/or acceptor-TT-acceptor (A-TT-A)-based materials.

FIG. 12 is a chemical formula showing an example of an n-type organic semiconductor material. The n-type organic semiconductor material may include fullerene, a fullerene derivative, a sub-phthalocyanine or sub-phthalocyanine derivative, a thiophene or thiophene derivative, and/or a compound represented by the formula shown in FIG. 12. In the formula of FIGS. 12, X₁ and X₂ may independently include O or NRₐ, and Rₐ may include at least one of hydrogen, deuterium, a substituted or unsubstituted C1 to C30 alkyl group, a substituted or unsubstituted C1 to C30 alkoxy group, a substituted or unsubstituted C6 to C30 aryl group, a substituted or unsubstituted C₃ to C₃₀ heterocyclic group, halogen, and a cyano group. In addition, R₁, R₂, R₃, and R₄ may each independently include hydrogen, deuterium, a substituted or unsubstituted C₁ to C30 alkyl group, a substituted or unsubstituted C₁ to C30 alkoxy group, a substituted or unsubstituted C6 to C30 aryl group, a substituted or unsubstituted C₃ to C₃₀ heterocyclic group, a halogen, a cyano group, or a combination thereof.

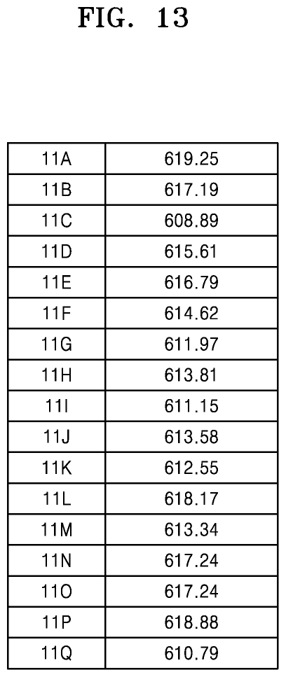

One molecule of the materials shown in FIGS. 11A to 11Q may have maximum absorption peaks in a solvent within a wavelength range of about 570 nm to about 585 nm. However, when the materials are deposited in the resonating structure shown in FIG. 9 or FIG. 10, an absorption characteristic may be shifted to about 20 nm to about 40 nm toward the long wavelength. FIG. 13 is a table showing an example of absorption peak wavelengths of p-type organic semiconductor materials shown in FIGS. 11A to 11Q. Referring to FIG. 13, the p-type organic semiconductor materials in the pixel array 900 or 900a of FIG. 9 or FIG. 10 may have maximum absorption peaks within a wavelength range of about 610 nm to about 620 nm. Therefore, the red pixel R may be configured to mostly absorb red light components without absorbing yellow light components.

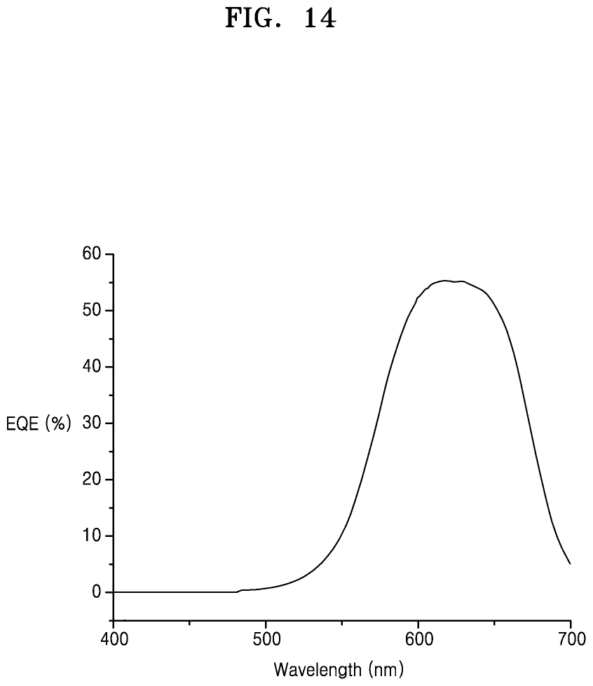

FIG. 14 is a diagram showing an example of an absorption spectrum of a red pixel R in the pixel array 900 of FIG. 9. When the pixel array 900 has a resonating structure including p-type organic semiconductor materials that may selectively absorb the red light, as shown in FIG. 14, the red pixel R may have an absorption spectrum having an absorption peak wavelength of about 620 nm and may rarely absorb the yellow light of about 590 nm or less.

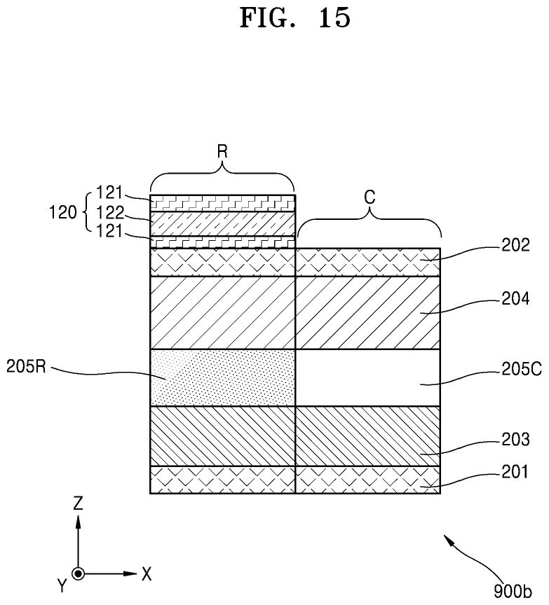

FIG. 15 is a cross-sectional view schematically showing a structure of a pixel array in an image sensor 1000, according to an embodiment. Referring to FIG. 15, a pixel array 900b may further include a band stop filter 120 arranged in the red pixel R. For example, the band stop filter 120 may be arranged to face the second electrode 202 of the red pixel R. In an embodiment, the band stop filter 120 may be arranged to come into contact with the upper surface of the second electrode 202 of the red pixel R. The band stop filter 120 may include and/or may be similar in many respects to the band stop filter 120 described above with reference to FIG. 3A, and may include additional features not mentioned above. For example, the band stop filter of FIG. 15 may block more yellow light when compared to the band stop filter 120 of FIG. 3A. Consequently, repeated descriptions of the band stop filter 120 described above with reference to FIG. 3A may be omitted for the sake of brevity.

The image sensor 1000, according to an embodiment, may be mounted in a vehicle and may be used as an image sensor for an autonomous vehicle. For example, the image sensor 1000 may be used to obtain traffic information such as, but not limited to, traffic signals. Alternatively or additionally, the image sensor 1000 may be used in combination with various electronic devices such as, but not limited to, a smart system, a general red/green/blue (RGB) camera, a depth-measurement camera, and the like, in a vehicle.

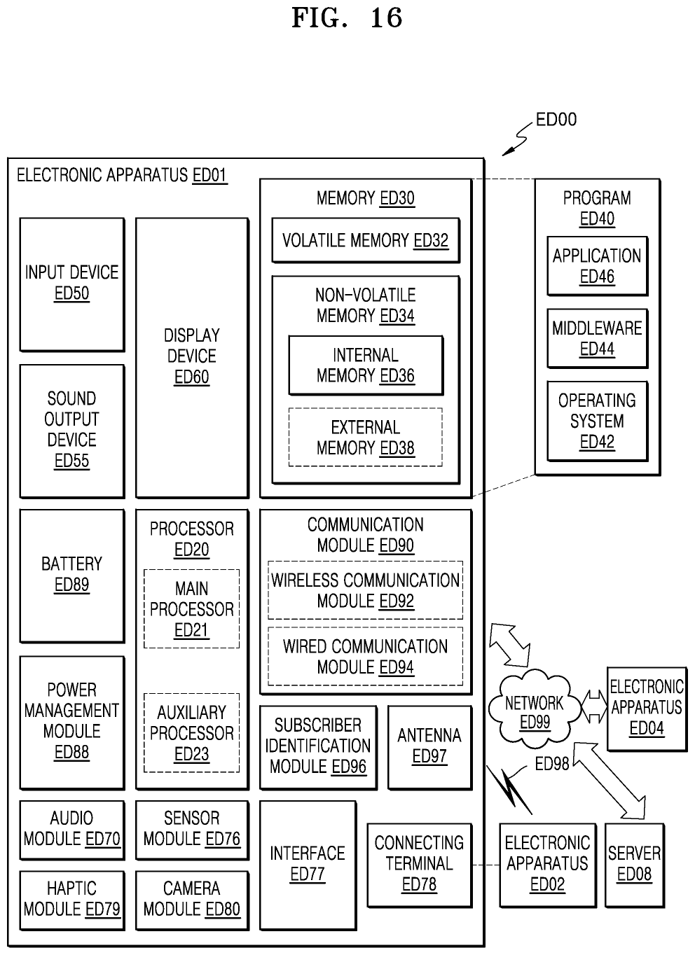

FIG. 16 is a block diagram showing an example of an electronic apparatus ED01 including the image sensor 1000. Referring to FIG. 16, in a network environment ED00, the electronic apparatus ED01 may communicate with another electronic apparatus ED02 via a first network ED98 (e.g., short-range wireless communication network, and the like) and/or may communicate with another electronic apparatus ED04 and/or a server ED08 via a second network ED99 (e.g., long-range wireless communication network, and the like) The electronic apparatus ED01 may communicate with the electronic apparatus ED04 via the server ED08. The electronic apparatus ED01 may include a processor ED20, a memory ED30, an input device ED50, a sound output device ED55, a display device ED60, an audio module ED70, a sensor module ED76, an interface ED77, a haptic module ED79, a camera module ED80, a power management module ED88, a battery ED89, a communication module ED90, a subscriber identification module ED96, and/or an antenna module ED97. In the electronic apparatus ED01, some of the elements (e.g., the display device ED60, and the like) may be omitted and/or another element may be added. Some of the elements may be configured as one integrated circuit. For example, the sensor module ED76 (e.g., a fingerprint sensor, an iris sensor, an illuminance sensor, and the like) may be embedded and implemented in the display device ED60 (e.g., a display, and the like).

The processor ED20 may control one or more elements (e.g., hardware, software elements, and the like) of the electronic apparatus ED01 connected to the processor ED20 by executing software (e.g., program ED40, and the like) and may perform various data processing or operations. As a part of the data processing or operations, the processor ED20 may load a command and/or data received from another element (e.g., the sensor module ED76, the communication module ED90, and the like) to a volatile memory ED32, may process the command and/or data stored in the volatile memory ED32, and may store result data in a non-volatile memory ED34. The processor ED20 may include a main processor ED21 (e.g., a central processing unit, an application processor, and the like) and an auxiliary processor ED23 (e.g., a graphics processing unit, an image signal processor, a sensor hub processor, a communication processor, and the like) that may operate independently from and/or along with the main processor ED21. The auxiliary processor ED23 may use less power than that of the main processor ED21 and may perform specific functions.

The auxiliary processor ED23, on behalf of the main processor ED21 while the main processor ED21 is in an inactive state (sleep state) or along with the main processor ED21 while the main processor ED21 is in an active state (application execution state), may control functions and/or states related to some of the elements (e.g., the display device ED60, the sensor module ED76, the communication module ED90, and the like) in the electronic apparatus ED01. The auxiliary processor ED23 (e.g., an image signal processor, a communication processor, and the like) may be implemented as a part of another element (e.g., the camera module ED80, the communication module ED90, and the like) that may be functionally related thereto.

The memory ED30 may store various data required by the elements (e.g., the processor ED20, the sensor module ED76, and the like) of the electronic apparatus ED01. The data may include, for example, input data and/or output data about software (e.g., program ED40, and the like) and commands related thereto. The memory ED30 may include the volatile memory ED32 and/or the non-volatile memory ED34.

The program ED40 may be stored as software in the memory ED30 and may include an operation system ED42, middleware ED44, and/or an application ED46.

The input device ED50 may receive commands and/or data to be used in the elements (e.g., the processor ED20, and the like) of the electronic apparatus ED01, from outside (e.g., a user, and the like) of the electronic apparatus ED01. The input device ED50 may include a microphone, a mouse, a keyboard, and/or a digital pen (stylus pen).

The sound output device ED55 may output a sound signal to outside of the electronic apparatus ED01. The sound output device ED55 may include a speaker and/or a receiver. The speaker may be used for a general purpose such as multimedia reproduction or record play, and the receiver may be used to receive a call. The receiver may be coupled as a part of the speaker and/or may be implemented as an independent device.

The display device ED60 may provide visual information to outside of the electronic apparatus ED01. The display device ED60 may include a display, a hologram device, or a projector, and a control circuit for controlling the corresponding device. The display device ED60 may include touch circuitry set to sense a touch, and/or a sensor circuit (e.g., pressure sensor, and the like) that may be set to measure the strength of a force generated by the touch.

The audio module ED70 may convert sound into an electrical signal and/or may convert an electrical signal into sound. The audio module ED70 may acquire sound through the input device ED50, and/or may output sound via the sound output device ED55, a speaker, and/or headphones of another electronic apparatus (e.g., the electronic apparatus ED02, and the like) connected directly and/or wirelessly to the electronic apparatus ED01.

The sensor module ED76 may sense an operating state (e.g., power, temperature, and the like) of the electronic apparatus ED01, or an outer environmental state (e.g., user state, and the like) and may generate an electrical signal and/or data value corresponding to the sensed state. The sensor module ED76 may include a gesture sensor, a gyro-sensor, a pressure sensor, a magnetic sensor, an acceleration sensor, a grip sensor, a proximity sensor, a color sensor, an infrared (IR) ray sensor, a vivo sensor, a temperature sensor, a humidity sensor, and/or an illuminance sensor.

The interface ED77 may support one or more designated protocols that may be used in order for the electronic apparatus ED01 to be directly (wired) and/or wirelessly connected to another electronic apparatus (e.g., the electronic apparatus ED02, and the like) The interface ED77 may include a high-definition multimedia interface (HDMI), a universal serial bus (USB) interface, Secure Digital (SD) card interface, and/or an audio interface.

The connection terminal ED78 may include a connector by which the electronic apparatus ED01 may be physically connected to another electronic apparatus (e.g., the electronic apparatus ED02, and the like). The connection terminal ED78 may include an HDMI connector, a USB connector, an SD card connector, and/or an audio connector (e.g., headphones connector, and the like).

The haptic module ED79 may convert an electrical signal into a mechanical stimulation (e.g., vibration, motion, and the like) or an electric stimulation that the user may sense through a tactile or motion sensation. The haptic module ED79 may include a motor, a piezoelectric device and/or an electric stimulus device.

The camera module ED80 may capture a still image and/or a video. The camera module ED80 may include a lens assembly including one or more lenses, the image sensor 1000 of FIG. 1, image signal processors, and/or flashes. The lens assembly included in the camera module ED80 may collect light emitted from an object that is an object to be captured.

The power management module ED88 may manage the power supplied to the electronic apparatus ED01. The power management module ED88 may be implemented as a part of a power management integrated circuit (PMIC).

The battery ED89 may supply electric power to components of the electronic apparatus ED01. The battery ED89 may include a primary battery that is not rechargeable, a secondary battery that is rechargeable, and/or a fuel cell. However, the present disclosure is not limited in this regard, and the battery ED89 may include other types of batteries and/or combinations of batteries.

The communication module ED90 may support the establishment of a direct (wired) communication channel and/or a wireless communication channel between the electronic apparatus ED01 and another electronic apparatus (e.g., the electronic apparatus ED02, the electronic apparatus ED04, the server ED08, and the like), and execution of communication through the established communication channel. The communication module ED90 may be operated independently from the processor ED20 (e.g., an application processor, and the like) and may include one or more communication processors that support the direct communication and/or the wireless communication. The communication module ED90 may include a wireless communication module ED92 (e.g., a cellular communication module, a short-range wireless communication module, a global navigation satellite system (GNSS) communication module, and the like) and/or a wired communication module ED94 (e.g., a local area network (LAN) communication module, a power line communication module, and the like). From among the communication modules, a corresponding communication module may communicate with another electronic apparatus via the first network ED98 (e.g., a short-range communication network such as, but not limited to, Bluetooth™, Wi-Fi based on the Institute of Electrical and Electronics Engineers (IEEE 802.11) standard (e.g., Wi-Fi Direct), or Infrared Data Association (IrDA)) or a second network ED99 (e.g., a long-range communication network such as a cellular network, Internet, or computer network (e.g., LAN, wide area network (WAN), and the like)). The various kinds of communication modules may be integrated as one element (e.g., a single chip, and the like) and/or may be implemented as a plurality of elements (e.g., a plurality of chips) separately from one another. The wireless communication module ED92 may identify and authenticate the electronic apparatus ED01 in a communication network, such as the first network ED98 and/or the second network ED99, by using subscriber information (e.g., an international mobile subscriber identifier (IMSI), and the like) stored in the subscriber identification module ED96.

The antenna module ED97 may transmit and/or receive a signal and/or power to/from outside (e.g., another electronic apparatus, and the like). An antenna may include a radiator formed as a conductive pattern formed on a substrate (e.g., printed circuit board (PCB), and the like). The antenna module ED97 may include one or more antennas. When the antenna module ED97 includes a plurality of antennas, an antenna that may be suitable for the communication type used in the communication network, such as the first network ED98 and/or the second network ED99, may be selected from among the plurality of antennas by the communication module ED90. The signal and/or the power may be transmitted between the communication module ED90 and another electronic apparatus via the selected antenna. Another component (e.g., a radio-frequency integrated circuit (RFIC), and the like) other than the antenna may be included as a part of the antenna module ED97.

Some of the elements may be connected to one another via the communication method among the peripheral devices (e.g., bus, general purpose input and output (GPIO), serial peripheral interface (SPI), mobile industry processor interface (MIPI), and the like) and may exchange signals (e.g., commands, data, and the like).

The command and/or data may be transmitted and/or received between the electronic apparatus ED01 and the external electronic apparatus ED04 via the server ED08 connected to the second network ED99. Other electronic apparatuses ED02 and ED04 may be and/or may include devices that may be substantially similar and/or the same as the electronic apparatus ED01. However, the present disclosure is not limited in this regard, and electronic apparatuses ED02 and ED04 may be different kinds of devices from the electronic apparatus ED01. All or some of the operations executed in the electronic apparatus ED01 may be executed in one or more devices among the other electronic apparatuses ED02, ED04, and ED08. For example, when the electronic apparatus ED01 has to perform a certain function and/or service, the electronic apparatus ED01 may request one or more other electronic apparatuses to perform some and/or an entire function and/or service, instead of executing the function and/or service by itself. One or more electronic apparatuses receiving the request may execute an additional function and/or service related to the request and may transfer a result of the execution to the electronic apparatus ED01. For example, a cloud computing, a distributed computing, or a client-server computing technique may be used.

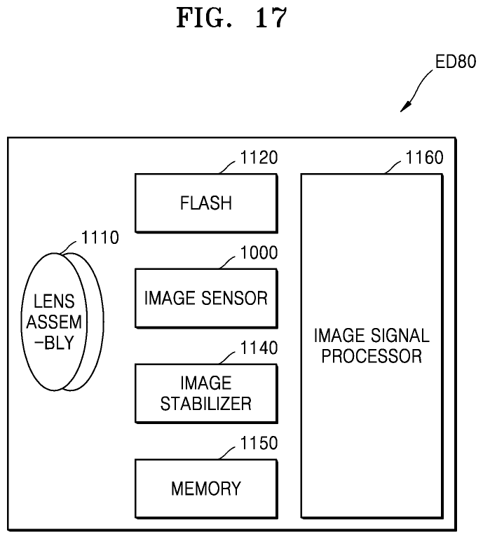

FIG. 17 is a block diagram showing an example of the camera module ED80 included in the electronic apparatus ED01 of FIG. 16. Referring to FIG. 17, the camera module ED80 may include a lens assembly 1110, a flash 1120, an image sensor 1000, an image stabilizer 1140, a memory 1150 (e.g., buffer memory, and the like), and/or an image signal processor 1160. The lens assembly 1110 may collect light emitted from an object that is to be captured. The camera module ED80 may include a plurality of lens assemblies 1110. For example, the camera module ED80 may be and/or may include a dual camera module, a 360-degree camera, a spherical camera, or the like. Some of the plurality of lens assemblies 1110 may have the same lens properties (e.g., viewing angle, focal length, auto-focus, F number, optical zoom, and the like) and/or different lens properties. The lens assembly 1110 may include, but not be limited to, a wide-angle lens, a telephoto lens, or the like.

The flash 1120 may emit light that may be used to strengthen the light emitted and/or reflected from the object. The flash 1120 may emit visible light, infrared (IR) ray light, or the like. The flash 1120 may include one or more light-emitting diodes (LEDs) (e.g., RGB LED, white LED, infrared LED, ultraviolet LED, and the like), and/or a Xenon lamp. The image sensor 1000 may include and/or may be similar in many respects to the image sensor described above with reference to FIG. 1, and may include additional features not mentioned above. The image sensor 1000 may convert the light emitted and/or reflected from the object and transferred through the lens assembly 1110 into an electrical signal to obtain an image corresponding to the object.

The image stabilizer 1140, in response to a motion of the camera module ED80 and/or the electronic apparatus 1101 including the camera module ED80, may move one or more lenses included in the lens assembly 1110 and/or the image sensor 1000 in a certain direction and/or may control the operating characteristics of the image sensor 1000 (e.g., adjusting of a read-out timing, and the like) in order to compensate for a negative influence of the motion. The image stabilizer 1140 may sense the movement of the camera module ED80 and/or the electronic apparatus ED01 by using a gyro sensor and/or an acceleration sensor disposed in or out of the camera module ED80. The image stabilizer 1140 may be implemented as an optical type.

The memory 1150 may store some or entire data of the image obtained through the image sensor 1000 for next image processing operation. For example, when a plurality of images are obtained at high speed, obtained raw data may be stored in the memory 1150 and only low-resolution images may be displayed. Subsequently, raw data of a selected image (e.g., due to user selection, and the like) may be transferred to the image signal processor 1160. The memory 1150 may be integrated with the memory ED30 of the electronic apparatus ED01, and/or may include an additional memory that may be operated independently.

The image signal processor 1160 may perform image treatment on the image obtained through the image sensor 1000 and/or the image data stored in the memory 1150. The image treatments may include a depth map generation, a three-dimensional (3D) modeling, a panorama generation, extraction of features, an image combination, and/or an image compensation (e.g., noise reduction, resolution adjustment, brightness adjustment, blurring, sharpening, softening, and the like). The image signal processor 1160 may perform controlling (e.g., exposure time control, read-out timing control, and the like) of the elements (e.g., image sensor 1000, and the like) included in the camera module ED80. In an embodiment, the image signal processor 1160 may generate an image by executing a demosaic algorithm. For example, the image signal processor 1160 may generate high-resolution black-and-white images through the clear channels, generate red images through red channels, and generate blue images through blue channels.

The image processed by the image signal processor 1160 may be stored again in the memory 1150 for additional process, and/or may be provided to an external element of the camera module ED80 (e.g., the memory ED30, the display device ED60, the electronic apparatus ED02, the electronic apparatus ED04, the server ED08, and the like). The image signal processor 1160 may be integrated with the processor ED20, and/or may be configured as an additional processor that may be independently operated from the processor ED20. When the image signal processor 1160 is configured as an additional processor separately from the processor ED20, the image processed by the image signal processor 1160 may go through an additional image treatment by the processor ED20 and may be displayed on the display device ED60.

In an embodiment, the image signal processor 1160 may receive two output signals independently from the adjacent photosensitive cells in each pixel and/or sub-pixel of the image sensor 1000, and may generate an auto-focusing signal from a difference between the two output signals. The image signal processor 1160 may control the lens assembly 1110 such that the focus of the lens assembly 1110 may be accurately formed on the surface of the image sensor 1000 based on the auto-focusing signal.

The electronic apparatus ED01 may further include one or a plurality of camera modules having different properties and/or functions. The camera module may include elements similar to those of the camera module ED80 of FIG. 17, and the image sensor included in the camera module may be implemented as a CCD sensor and/or a CMOS sensor, and may include one or a plurality of sensors selected from the image sensors having different properties, such as, but not limited to, an RGB sensor, a black and white (BW) sensor, an IR sensor, or a ultraviolet (UV) sensor. For example, one of the plurality of camera modules ED80 may include a wide-angle camera and another camera module ED80 may include a telephoto camera. Similarly, one of the plurality of camera modules ED80 may include a front camera and another camera module ED80 may include a rear camera.

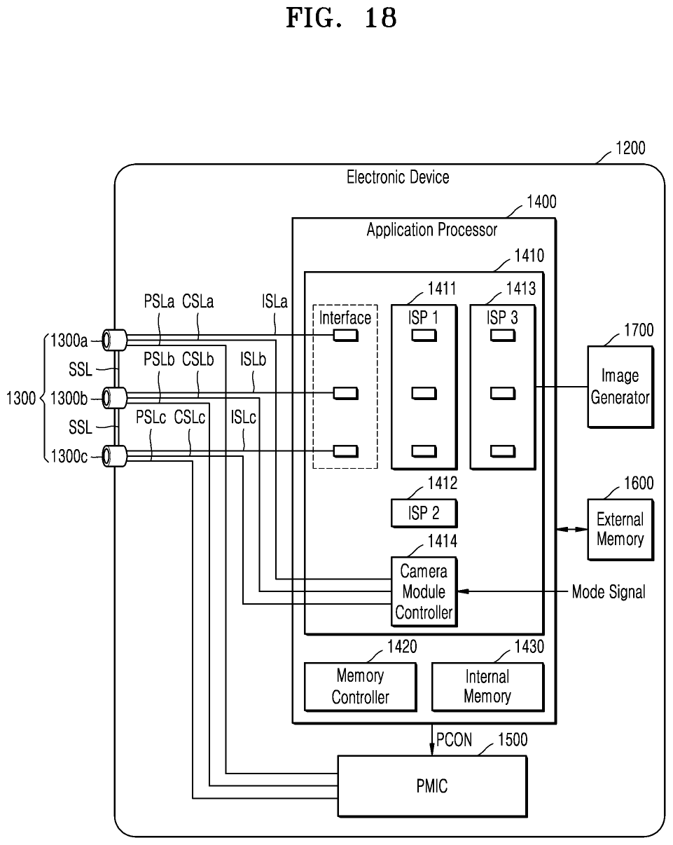

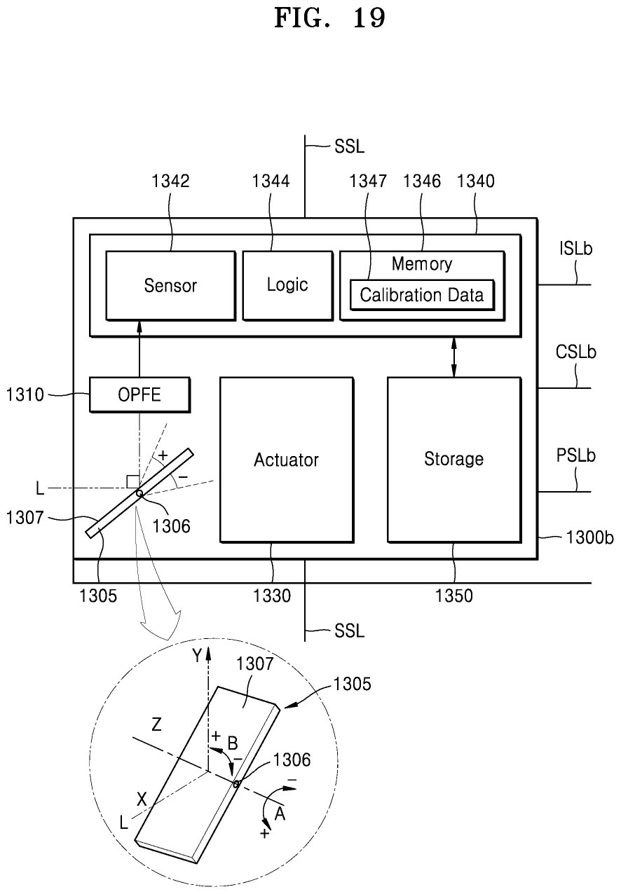

FIG. 18 is a block diagram of an electronic device 1200 including a multi-camera module, according to an embodiment. FIG. 19 is a detailed block diagram of the camera module in the electronic device shown in FIG. 18, according to an embodiment.

Referring to FIG. 18, the electronic device 1200 may include a camera module group 1300, an application processor 1400, a PMIC 1500, an external memory 1600, and an image generator 1700.

The camera module group 1300 may include a plurality of camera modules (e.g., first camera module 1300a, second camera module 1300b, and third camera module 1300c). Although the drawings show an example in which three (3) camera modules 1300a to 1300c are arranged, the present disclosure is not limited thereto. In some embodiments, the camera module group 1300 may be modified to include only two (2) camera modules. Also, in some embodiments, the camera module group 1300 may be modified to include four (4) or more camera modules.

Hereinafter, detailed configuration of the second camera module 1300b is described in detail below with reference to FIG. 19, but the description provided below may be also applied to the other camera modules (e.g., the first camera module 1300a and the third camera module 1300c), according to the embodiments.

Referring to FIG. 19, the second camera module 1300b may include a prism 1305, an optical path folding element (OPFE) 1310, an actuator 1330, an image sensing device 1340, and a storage 1350.

The prism 1305 may include a reflecting surface 1307 having a light-reflecting material and may deform a path of light L incident from outside.

In some embodiments, the prism 1305 may change the path of the light L incident in the first direction (X-direction) into a second direction (Y-direction) that is perpendicular to the first direction (X-direction). The prism 1305 may rotate the reflecting surface 1307 having the light-reflecting material about a center axis 1106 in a direction A, or about the center axis 1306 in a direction B such that the path of the light L incident in the first direction (X-direction) may be changed to the second direction (Y-direction) perpendicular to the first direction (X-direction). The OPFE 1310 may also move in the third direction (Z-direction) that is perpendicular to the first direction (X-direction) and the second direction (Y-direction).

In some embodiments, as shown in the drawings, the maximum rotation angle of the prism 1305 in the direction A is 15° or less in the positive A direction and is greater than 15° in the negative A direction, but the present disclosure is not limited thereto.

In some embodiments, the prism 1305 may be moved by the angle of about 20°, between about 10° to about 20°, or between about 15° to about 20° in the positive or negative B direction. As used herein, the moving angle may be the same in the positive or negative B direction, and/or may be substantially similar within a range of about 1°.

In some embodiments, the prism 1305 may move the reflecting surface 1307 of the light-reflective material in the third direction (e.g., Z direction) that is parallel to the direction in which the center axis 1306 extends.

The OPFE 1310 may include, for example, optical lenses formed as m groups, where m is a positive integer greater than zero (0). The m lenses may move in the second direction (Y-direction) and may change an optical zoom ratio of the camera module 1300b. For example, when a basic optical zoom ratio of the camera module 1300b is Z and m optical lenses included in the OPFE 1310 move, the optical zoom ratio of the camera module 1300b may be changed to 3Z, 5Z, or 10Z or greater.

The actuator 1330 may move the OPFE 1310 and/or the optical lens (hereinafter referred to as optical lens) to a certain position. For example, the actuator 1330 may adjust the position of the optical lens such that the image sensor 1342 may be located at a focal length of the optical lens for exact sensing operation.

An image sensing device 1340 may include the image sensor 1342, a control logic 1344, and a memory 1346. The image sensor 1342 may sense an image of a sensing target by using the light L provided through the optical lens. The control logic 1344 may control the overall operation of the camera module 1300b. For example, the control logic 1344 may control the operations of the camera module 1300b according to a control signal provided through a control signal line CSLb.

For example, the image sensor 1342 may include the color separating lens array or the nano-photonic lens array described above. The image sensor 1342 may receive more signals separated according to wavelengths in each pixel by using the color separating lens array based on the nano-structures. Due to the above effects, the optical intensity needed to generate high quality images of high resolution and under the low illuminance may be secured.

The memory 1346 may store information that may be needed for the operation of the camera module 1300b (e.g., calibration data 1347). The calibration data 1347 may include information that may be needed to generate image data by using the light L provided from outside through the camera module 1300b. The calibration data 1347 may include, for example, information about the degree of rotation described above, information about the focal length, information about an optical axis, and the like. When the camera module 1300b is implemented in the form of a multi-state camera of which the focal length is changed according to the position of the optical lens, the calibration data 1347 may include information related to focal length values of the optical lens according to each position (or state) and auto-focusing.

The storage unit 1350 may store image data sensed through the image sensor 1342. The storage unit 1350 may be disposed out of the image sensing device 1340 and may be stacked with a sensor chip included in the image sensing device 1340. In some embodiments, the storage unit 1350 may be implemented as electrically erasable programmable read-only memory (EEPROM), however, the present disclosure is not limited thereto.

Referring to FIGS. 18 and 19, in some embodiments, each of the plurality of camera modules 1300a to 1300c may include the actuator 1330. Accordingly, each of the plurality of camera modules 1300a to 1300c may include the calibration data 1347 that may be the same as and/or different from the others, according to the operation of the actuator 1330 included therein.

In some embodiments, one (e.g., the second camera module 1300b) of the plurality of camera modules 1300a to 1300c (e.g., the second camera module 1300b) may be a camera module in a folded lens type including the prism 1305 and the OPFE 1310 described above, and the other camera modules (e.g., the first camera module 1300a and the third camera module 1300c) may be and/or may include vertical type camera modules not including the prism 1305 and the OPFE 1310. However, the present disclosure is not limited thereto.

In some embodiments, one of the plurality of camera modules 1300a to 1300c (e.g., the third camera module 1300c) may be a depth camera of a vertical type, which may extract depth information by using an IR ray.

In some embodiments, at least two camera modules from among the plurality of camera modules 1300a to 1300c (e.g., the first camera module 1300a and the second camera module 1300b) may have different fields of view. For example, the optical lenses of the at least two camera modules from among the plurality of camera modules 1300a to 1300c (e.g., the first camera module 1300a and the second camera module 1300b) may be different from each other. However, the present disclosure is not limited thereto.

In some embodiments, the plurality of camera modules 1300a to 1300c may have different fields of view from one another. For example, the optical lenses respectively included in the plurality of camera modules 1300a to 1300c may be different from one another, however, the present disclosure is not limited thereto.

In some embodiments, the plurality of camera modules 1300a to 1300c may be physically isolated from one another. That is, the sensing region of one image sensor 1342 may not be divided and used by the plurality of camera modules 1300a to 1300c, but the plurality of camera modules 1300a to 1300c may each have an independent image sensor 1342 provided therein.

Referring back to FIG. 18, the application processor 1400 may include an image processing device 1410, a memory controller 1420, and an internal memory 1430. The application processor 1400 may be separately implemented from the plurality of camera modules 1300a to 1300c. For example, the application processor 1400 and the plurality of camera modules 1300a to 1300c may be separately implemented as separate semiconductor chips.

The image processing device 1410 may include a plurality of image processors (e.g., first image processor 1411, second image processor 1412, and third image processor 1413), and a camera module controller 1414.

The image data generated by each of the camera modules 1300a to 1300c may be provided to the image processing device 1410 via separate image signal lines, respectively. The image data transfer may be carried out by using a camera serial interface (CSI) based on a MIPI, for example. However, the present disclosure is not limited thereto.

The image data transferred to the image processing device 1410 may be stored in an external memory 1600 before being transferred to the first and second image processors 1411 and 1412. The image data stored in the external memory 1600 may be provided to the first image processor 1411 and/or the second image processor 1412. The first image processor 1411 may correct the image data in order to generate video. The second image processor 1412 may correct the image data in order to generate still images. For example, the first and second image processors 1411 and 1412 may perform a pre-processing operation such as, but not limited to, a color calibration, a gamma calibration on the image data.

The first image processor 1411 may include sub-processors. When the number of sub-processors is equal to the number of camera modules 1300a to 1300c, each of the sub-processors may process the image data provided from a corresponding camera module. When the number of sub-processors is less than the number of camera modules 1300a to 1300c, at least one of the sub-processors may process the image data provided from a plurality of camera module 1300a to 1300c by using a timing-sharing process. The image data processed by the first image processor 1411 and/or the second image processor 1412 may be stored in the external memory 1600 before being transferred to the third image processor 1413. The image data stored in the external memory 1600 may be transferred to the second image processor 1412. The second image processor 1412 may perform a post-processing operation such as, but not limited to, a noise calibration, a sharpen calibration, and the like, on the image data.

The image data processed in the third image processor 1413 may be provided to the image generator 1700. The image generator 1700 may generate a final image by using the image data provided from the third image processor 1413 according to image generating information or a mode signal.

That is, the image generator 1700 may generate by merging at least parts of the image data generated by the camera modules 1300a to 1300c having different fields of view, according to image generating information and/or the mode signal. In an embodiment, the image generator 1700 may generate the output image by selecting one of pieces of image data generated by the camera modules 1300a to 1300c having different fields of view, according to image generating information or the mode signal.

In some embodiments, the image generating information may include a zoom signal or a zoom factor. For example, the mode signal may be and/or may include a signal based on a mode selected by a user.

When the image generating information is a zoom signal (zoom factor) and the plurality of camera modules 1300a to 1300c have different fields of view (angles of view) from one another, the image generator 1700 may perform different operations according to the type of zoom signal. For example, when the zoom signal is a first signal, the image data output from the first camera module 1300a may be merged with the image data output from the third camera module 1300c, and the output image may be generated by using the merged image signal and the image data output from the second camera module 1300b and not used in the merge. When the zoom signal is a second signal that is different from the first signal, the image generator 1700 may not perform the image data merging, and may generate the output image by selecting one piece of the image data output respectively from the plurality of camera modules 1300a to 1300c. However, the present disclosure is not limited thereto, and the method of processing the image data may be modified as needed.

The camera module controller 1414 may provide each of the plurality of camera modules 1300a to 1300c with a control signal. The control signals generated by the camera module controller 1414 may be provided to corresponding camera modules 1300a to 1300c via control signal lines (e.g., first control signal line CSLa, second control signal line CSLb, and third control signal line CSLc) separated from one another.

In some embodiments, the control signal provided to the plurality of camera modules 1300a to 1300c from the camera module controller 1414 may include mode information according to the mode signal. The plurality of camera modules 1300a to 1300c may operate in a first operation mode and/or a second operation mode in relation to the sensing speed, based on the mode information.

In the first operation mode, the plurality of camera modules 1300a to 1300c may generate the image signal at a first speed (e.g., generating an image signal of a first frame rate), may encode the image signal at a second speed that may be faster than the first speed (e.g., may encode the image signal at a second frame rate that may be greater than the first frame rate), and may transfer the encoded image signal to the application processor 1400. For example, the second speed may be 30 times faster than the first speed or less.

The application processor 1400 may store the received image signal (e.g., the encoded image signal) in the memory 1430 provided therein and/or the storage 1600 outside the application processor 1400 The application processor 1400 may decode the encoded signal from the memory 1430 and/or the storage 1600, and may display the image data generated based on the decoded image signal. For example, the first and second image processors 1411 and 1412 in the image processing device 1410 may perform decoding, and may perform image processing on the decoded image signals.

In the second operation mode, the plurality of camera modules 1300a to 1300c may generate an image signal at a third speed that may be slower than the first speed (e.g., generating the image signal at a third frame rate that may be lower than the first frame rate), and may transfer the image signal to the application processor 1400. The image signal provided to the application processor 1400 may be a signal that is not encoded. The application processor 1400 may perform the image processing of the received image signal and/or store the image signal in the memory 1430 and/or the storage 1600.

The PMIC 1500 may supply the power, for example, the power voltage, to each of the plurality of camera modules 1300a to 1300c. For example, the PMIC 1500 may supply the first power to the first camera module 1300a via a first power signal line PSLa, the second power to the second camera module 1300b via a second power signal line PSLb, and the third power to the third camera module 1300c via a third power signal line PSLc, under the control of the application processor 1400.

The PMIC 1500 may generate the power corresponding to each of the plurality of camera modules 1300a to 1300c and may adjust the power level, in response to a power control signal PCON from the application processor 1400. The power control signal PCON may include a power adjusting signal for each operation mode of the plurality of camera modules 1300a to 1300c. For example, the operation mode may include a low power mode, and the power control signal PCON may include information about the camera module operating in the low-power mode and set power level. The levels of the power provided to the plurality of camera modules 1300a to 1300c may be equal to or different from each other. Alternatively or additionally, the power level may be dynamically changed.

It is to be understood that embodiments described herein should be considered in a descriptive sense only and not for purposes of limitation. Descriptions of features or aspects within each embodiment may typically be considered as available for other similar features or aspects in other embodiments. While one or more embodiments have been described with reference to the figures, it is to be understood by those of ordinary skill in the art that various changes in form and details may be made therein without departing from the spirit and scope as defined by the following claims.

What is claimed is:

1. An image sensor, comprising:
a sensor substrate comprising a plurality of photosensitive cells configured to sense light;
a color filter layer on the sensor substrate, the color filter layer comprising a plurality of red color filters and a plurality of clear filters, the plurality of red color filters and the plurality of clear filters being alternately disposed; and
a band stop filter facing the color filter layer and configured to have an absorption spectrum having an absorption peak wavelength of 520 nanometers (nm) to 620 nm.

2. The image sensor of claim 1, wherein the band stop filter directly contacts upper surfaces of the plurality of red color filters.

3. The image sensor of claim 2, wherein the band stop filter comprises a plurality of first dielectric layers and at least one second dielectric layer, and
wherein the at least one second dielectric layer is disposed between two adjacent first dielectric layers of the plurality of first dielectric layers.

4. The image sensor of claim 3, wherein the plurality of first dielectric layers comprises a first dielectric material having a first refractive index,
wherein the at least one second dielectric layer comprises a second dielectric material having a second refractive index, and
wherein the second refractive index is different from the first refractive index.

5. The image sensor of claim 4, wherein the first dielectric material of the plurality of first dielectric layers and the second dielectric material of the at least one second dielectric layer each comprise at least one of TiO₂, SiO₂, SiN, Ta₂O₅, HfO₂, NbO₂, MgF₂, Si, Al₂O₃, or SiON.

6. The image sensor of claim 4, wherein each layer of the plurality of first dielectric layers and the at least one second dielectric layer has a thickness of 10 nm to 1000 nm.

7. The image sensor of claim 2, wherein the band stop filter comprises:
a first reflective layer;
a second reflective layer facing the first reflective layer; and
a dielectric layer between the first reflective layer and the second reflective layer.

8. The image sensor of claim 7, wherein the first reflective layer and the second reflective layer each comprise at least one reflective metal material from aluminum (Al), argentum (Ag), aurum (Au), tungsten (W), molybdenum (Mo), or nickel (Ni), and
wherein the first reflective layer and the second reflective layer each have a thickness of 0.5 nm to 10 nm.

9. The image sensor of claim 7, wherein the dielectric layer comprises at least one of TiO₂, SiO₂, SiN, Ta₂O₅, HfO₂, NbO₂, MgF₂, Si, Al₂O₃, or SiON.

10. The image sensor of claim 7, wherein the first reflective layer and the second reflective layer form a resonator, and
wherein a distance between the first reflective layer and the second reflective layer and a refractive index of the dielectric layer are selected such that a resonant wavelength of the resonator matches the absorption peak wavelength of the band stop filter.

11. The image sensor of claim 1, wherein the band stop filter is spaced apart from the color filter layer and at least partially covering a region of the color filter layer.

12. The image sensor of claim 11, wherein the band stop filter comprises a plurality of first dielectric layers and a plurality of second dielectric layers that are alternately disposed,
wherein the plurality of first dielectric layers comprises a first dielectric material having a first refractive index,
wherein the plurality of second dielectric layers comprises a second dielectric material having a second refractive index, and
wherein the second refractive index is different from the first refractive index.

13. The image sensor of claim 12, wherein the first dielectric material of the plurality of first dielectric layers and the second dielectric material of the plurality of second dielectric layers each comprise at least one of TiO₂, SiO₂, SiN, Ta₂O₅, HfO₂, NbO₂, MgF₂, Si, Al₂O₃, or SiON.

14. The image sensor of claim 12, wherein a difference between the first refractive index of the plurality of first dielectric layers and the second refractive index of the plurality of second dielectric layers is less than or equal to 1, and
wherein a full width at half maximum (FWHM) of the absorption spectrum of the band stop filter is less than or equal to 100 nm.

15. An image sensor, comprising:
a red pixel comprising a first electrode, a second electrode, and a first active layer between the first electrode and the second electrode; and
a clear pixel comprising a third electrode, a fourth electrode, and a second active layer between the third electrode and the fourth electrode,
wherein the first active layer comprises:
a p-type organic semiconductor material configured to selectively absorb red light; and
an n-type organic semiconductor material configured to receive electrons from the p-type organic semiconductor material that is excited by the absorbed red light, and
wherein the first electrode and the second electrode form a resonator having a resonant wavelength of 610 nanometers (nm) to 630 nm.

16. The image sensor of claim 15, wherein the first active layer comprises a bulk heterojunction structure in which the p-type organic semiconductor material and the n-type organic semiconductor material are co-deposited in one layer.

17. The image sensor of claim 15, wherein the first active layer comprises a p-type organic semiconductor layer adjacent to the first electrode and an n-type organic semiconductor layer adjacent to the second electrode,
wherein the p-type organic semiconductor layer comprises the p-type organic semiconductor material configured to selectively absorb red light, and
wherein the n-type organic semiconductor layer comprises the n-type organic semiconductor material configured to receive electrons from the p-type organic semiconductor material excited by the absorbed red light.

18. The image sensor of claim 15, wherein the second active layer comprises:
a first p-type organic semiconductor material configured to absorb red light,
a second p-type organic semiconductor material configured to absorb green light,
a third p-type organic semiconductor material configured to absorb blue light, and
the n-type organic semiconductor material configured to receive electrons from excited p-type organic semiconductor material.

19. The image sensor of claim 15, further comprising:
a band stop filter facing the second electrode of the red pixel and configured to have an absorption spectrum with an absorption peak wavelength of 520 nanometers (nm) to 620 nm.

20. An electronic apparatus, comprising:
a lens assembly configured to form an optical image of a subject;
an image sensor configured to convert the optical image formed by the lens assembly into an electrical signal; and
a processor configured to process a signal generated by the image sensor,
wherein the image sensor comprises:
a sensor substrate comprising a plurality of photosensitive cells configured to sense light;
a color filter layer on the sensor substrate, the color filter layer comprising a plurality of red color filters and a plurality of clear filters, the plurality of red color filters and the plurality of clear filters being alternately disposed; and
a band stop filter facing the color filter layer and configured to have an absorption spectrum having an absorption peak wavelength of 520 nanometers (nm) to 620 nm.
